(19) United States
(12) Patent Application Publication
(10) Pub. No.: US 2009/0286097 A1
(43) Pub. Date: Nov. 19, 2009

(54) Electrically conducting poylmer glue, devices made therewith and methods of manufacture

(75) Inventors: Yang Yang, Los Angles, CA (US); Jianyong Ouyang, Los Angeles, CA (US)

Correspondence Address: VENABLE LLP, P.O. BOX 34385, WASHINGTON, DC, 20043-9998, US

(73) Assignee: The Regents of the University of California, Oakland, CA (US)

(21) Appl. No.: 11/922,051

(22) PCT Filed: Jun. 30, 2006
(86) PCT No.: PCT/US2006/025597

§ 371 Date: Dec. 12, 2007

Related U.S. Application Data
(60) Provisional application No. 60/695,514, filed on Jun. 30, 2005.

(51) Int. Cl. B32B 27/26; B32B 9/00; B32B 27/28; B32B 37/12; B32B 37/02; H01B 1/12

(52) U.S. Cl. 428/500; 428/411.1; 428/704; 428/532; 156/60; 156/275.5; 252/500

(57) ABSTRACT

An electronic or electro-optic device has a first device component, and a second device component attached to the first device component by a conducting polymer glue disposed between at least a portion of the first device component and the second device component. The conducting polymer glue provides an electrically conducting and mechanical connection between the first device component and the second device component. A method of producing an electronic or electro-optic device includes providing a first device component, providing a second device component proximate the first device component, and attaching the first device component to the second device component with a conducting polymer glue. A conducting polymer glue for connecting components of electronic or electro-optic devices includes a conducting polymer, and an organic additive. The conducting polymer glue is able to provide mechanical and electrical connection.

### CROSS-REFERENCE OF RELATED APPLICATION

This application claims priority to U.S. Provisional Application No. 60/695,514 filed Jun. 30, 2005, the entire contents of which are hereby incorporated by reference.

The U.S. Government has a paid-up license in this invention and the right in limited circumstances to require the patent owner to license others on reasonable terms as provided for by the terms of AFOSR Grant No. FA9550-0401-0215.

### BACKGROUND

1. Field of Invention

This application relates to electronic and electro-optic devices having components joined together by conducting polymer glue, methods of gluing together components of electronic and electro-optic devices, and to conducting polymer glue for gluing together components of electronic and electro-optic devices.

2. Discussion of Related Art

The contents of all references cited anywhere in this specification are hereby incorporated by reference.

Electronic materials and devices have made great progress in achieving useful new properties, such as high mechanical flexibility, low fabrication cost, and versatility of the chemical structure of organic materials. (See, for example, Handbook of Conducting Polymers, revised and expanded, Edition 2, ed. by Skotheim, T. A., Ekenbaumer, R. L. & Reynolds, S. R. New York, Marcel Dekker, (1998); Burroughes J. H. et al. Light-emitting diodes based on conjugated polymers. Nature 347, 539-541 (1990); Sariciftci, N. S., Smilowitz, L., Heeger, A. J. & Wudl, F. Photoinduced electron-transfer from a conducting polymer to buckminsterfullerene. Science 258, 1474-1476 (1992); Pei, Q. B., Yu, G., Zhang, C., Yang, Y. & Heeger, A. J. Polymer light-emitting electrochemical-cells. Science 269, 1086-1088, 1995; Dimitrakopoulos, C. D., & Mascaro, D. J. Organic thin-film transistors: A review of recent advances. IBM J. Res. Dev. 45, 11-27 (2001); and Ouyang, J., Chu C. W., Szmanda C. R., Ma, L. & Yang, Y. Programmable polymer thin film and non-volatile memory device. Nature Materials 3, 918-922 (2004).) Organic electronic devices have potential for many new applications. However, the advantages of organic materials have not been fully explored. For example, there is no report of the usage of conducting polymer as electric glue, though many applications have been discovered for conducting polymers based on the conductivity, the processibility, and the redox properties. Many organic materials have properties that render them suitable to provide glue, since organic materials usually have a low melting point, and their chemical structure can be readily modified so that they bind to other materials through a chemical reaction or crosslinking at a certain temperature or by exposure to light, for example.

The use as conducting polymer for providing electric glue can open new applications for conducting polymers. For example, it could replace conventional lead solders in electronic circuit boards in some applications. Such electric glue made from conducting polymers can also be compatible with other organic devices. In addition, electronic waste using conducting polymer as solder will be much easier to dispose of than that of waste that has lead solder. Thus, conducting polymer solder can be friendly to the environment. Another example of the application of conducting polymer for electric glue is the fabrication of organic electronic devices through a roll-to-roll process, which has been regarded as the most efficient and most economical way for organic device fabrication (Forrest, S., Burrows, P. & Thompson, M. The dawn of organic electronics. Organic semiconductors are strong candidates for creating flexible, full-color displays and circuits on plastic. IEEE Spectrum 37, 29-34 (2000); Kimmel, J., Hautanen, J. & Levola, T. Display technologies for portable communication devices. Proceedings of the IEEE 90, 581-590 (2002)). An important step to realize the roll-to-roll fabrication of organic electronic devices is the lamination of two films. Though both polymer photovoltaic cells and polymer light-emitting diodes fabricated through a lamination process have been reported by using sticky semiconductive polymers (Granstrom, M., Petritsch, K., Arias. A. C, Lux, A., Andersson, M. R. & Friend, R. H. Laminated fabrication of polymeric photovoltaic diodes. Nature 395, 257-260 (1998); Guo. T. F., Pvo, S., Chang, S. C. & Yang, Y. High performance polymer light-emitting diodes fabricated by a low temperature lamination process. Adv. Fund. Mater. 11, 339-343 (2001)), these methods are not suitable for practical applications. Electric glue using conducting polymers can be used to laminate organic semiconductive materials and conductive electrodes mechanically as well as electrically, so it may be suitable for almost all organic materials and is practical. Hence, there is a need for conducting polymer glue for use in making electronic and electro-optic devices.

### SUMMARY

Further objectives and advantages will become apparent from a consideration of the description, drawings, and examples.

An electronic or electro-optic device according to an embodiment of this invention has a first device component, and a second device component attached to the first device component by a conducting polymer glue disposed between at least a portion of the first device component and the second device component. The conducting polymer glue provides an electrically conducting and mechanical connection between the first device component and the second device component.

A method of producing an electronic or electro-optic device according to an embodiment of this invention includes providing a first device component, providing a second device component proximate the first device component, and attaching the first device component to the second device component with a conducting polymer glue. The conducting polymer glue provides an electrically conducting and mechanical connection between the first device component and the second device component.

A conducting polymer glue for connecting components of electronic or electro-optic devices according to an embodiment of this invention includes a conducting polymer selected from the group consisting of

poly(3,4-ethylenedioxythiophene) and its derivatives,

polythiophene and its derivatives,

polypyrrole and its derivatives,

polyaniline and its derivatives,

polyacetylene and its derivatives,

poly(para-phenylenevinylene) and its derivatives,

polypyridine and its derivatives,

polyfluorene and its derivatives,

polyindole and their derivatives, and

an organic additive selected from the group consisting of sorbital, erythritol, 1,4-dioxane-2,3-diol, threitol, arabinose, lyxose, ribose, xylose, xylulose, pentaerythritol, arabitol, xylitol, fucose, fructose, galactose, glucose, inositol, mannose, sorbose, iditol, mannitol, pinitol, 2-hydroxyethyl dodecyl sulfoxide, 4-bromophenyl methyl sulfoxide, polyvinylalcohol, poly(ethyleneoxide), poly(ethylene glycol), and derivatives including an addition of an epoxy group and carbon-carbon double bonds so that addition or crosslinking can be provided. The conducting polymer glue is able to provide mechanical and electrical connection.

### BRIEF DESCRIPTION OF THE DRAWINGS

The invention may be better understood by reading the following detailed description with reference to the accompanying figures in which:

FIGS. 1A-1C include a schematic illustration of an electronic or electro-optic device according to an embodiment of this invention and a method of manufacture of the device according to an embodiment of the invention;

FIG. 2A-2C show the chemical structure of PEDOT:PSS, D-sorbitol, and poly(vinyl alcohol), respectively, according to an embodiment of this invention;

FIGS. 3A and 3B show current-voltage and lightness-voltage curves of a laminated polymer light-emitting diode: plastic/Al/MEH-PPV/PEDOT:PSS(D-sorbitol)/ITO/plastic according to an embodiment of this invention; and

FIG. 4 shows the current-voltage curve of a laminated polymer photovoltaic cell: plastic/Al/P3HT+PCBM/PEDOT:PSS(D-sorbitol)/ITO/plastic, according to an embodiment of this invention.

### DETAILED DESCRIPTION

In describing embodiments of the present invention illustrated in the drawings, specific terminology is employed for the sake of clarity. However, the invention is not intended to be limited to the specific terminology so selected. It is to be understood that each specific element includes all technical equivalents which operate in a similar manner to accomplish a similar purpose.

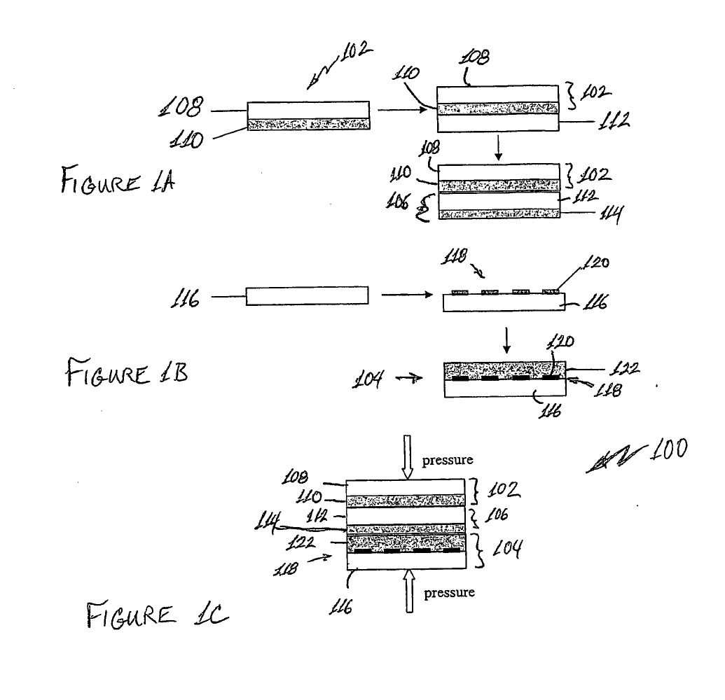

FIGS. 1A, 1B and 1C illustrate an example of an electronic or electro-optic device 100 and its method of manufacture according to an embodiment of this invention. An electronic or electro-optic device 100 according to an embodiment of this invention has a first device component 102 and a second device component 104 attached to the first device component by a conducting polymer glue 106 disposed between at least a portion of the first device component 102 and second device component 104 (FIG. 1C). The conducting polymer glue 106 provides an electrically conducting and mechanical connection between the first device component 102 and second device component 104. The conducting polymer glue 106 may be a blend of polymers and organic additives, may be a combination of layers of polymers and organic additives, or a combination thereof. A first device component 102 may be a single-component structure, or may be a multi-component structure. Similarly, the second device component 104 may be a single-component structure, or may be a multi-component structure.

The electronic or electro-optic device 100 may be a polymer light-emitting diode as one particular example of this embodiment of the invention. This example is shown to help illustrate some concepts of the invention. The invention is not limited to this one example. In this example, a plastic structure 108 has an indium tin oxide (ITO) 110 electrode layer formed thereon. A layer of PDOT:PSS 112 is formed on the first device component 102. The PDOT:PSS layer 112 may be formed, for example, by spin-coating. In this example, the conducting polymer 112 is PDOT:PSS, however, the invention is not limited to only this material.

A layer of an organic additive 114 is formed on the conducting polymer layer 112. The layer of organic additive 114 may be formed by spin-coating, for example, or by thermal deposition. Alternatively, the conducting glue 106 may be a blend of a conducting polymer and an additive instead of having a layer structure. Furthermore, additional alternatives are possible such as forming combinations of layers which may include blended material layers and the number of the layers may be selected to be more than two without departing from the general concepts of this invention. Still further alternatives include spraying the conductive polymer glue and/or components onto a surface or printing it on. The conductive polymer glue can be formed and used as conductive tape for applications such as, but not limited to, electrical contact and electrical discharges. In this particular example, the organic additive is D-sorbitol.

The second device component 104 has a substrate 116 and a plurality of electrodes 118 deposited thereon, such as electrode 120. The substrate may be plastic or glass in some embodiments, but could also be a metal, an insulator or a semiconductor, for example. The electrodes may be Al, for example, but could be selected from other materials according the specific application. For example, the electrodes could be Cu, Ag and/or Au in addition to AL, or combinations thereof. An active layer of organic semiconducting material 122 is deposited on the substrate 116 and electrodes 118. For example, the active organic semiconductor material 122 may be MEH-PPV. The conducting polymer glue 106 provides electrical conduction between the first device component 102 and the second device component 104. In addition, the conducting polymer glue 106 provides a mechanical connection joining the first device component 102 to the second device component 104. In this example, the electronic or electric-optic device is an organic light-emitting diode made by a laminating process in which the first device component 102 is laminated to the second device component 104 using conducting polymer glue 106. The general concepts of this invention are not limited to only organic light-emitting diodes and are not limited to only laminating processes. The conducting polymer glue 106 may be heated either before or after it is applied to the first device component 102 to cause it to join the first device component 102 and the second device component 104. Alternatively, conducting polymer glues may be selected such that they adhere upon application of other forms of energy such as being exposed to light or passing a current therethrough.

Electronic and/or electro-optic devices that have components joined together by electrically conducting polymer glue can include both organic and inorganic devices, such as, but not limited to, light-emitting diodes, photovoltaic cells, transistors, memory devices, electrochromic, displays, sensors, biosensors, liquid crystal displays, batteries, and devices that use nanotubes or nanoparticles.

Substrates, wires or materials of any other shape may be joined together, such as by lamination. Such structures may be formed from a metal, such as, but not limited to, stainless D steel, copper, aluminum; an insulator, such as, but not limited to glass, quartz, and silicon oxide; a semiconductor, such as, but not limited to, silicon, gallium, gallium nitride; and/or organic materials, such as, but not limited to polymers and small organic compounds.

Conducting polymers may include, but are not limited to the following (conjugated polymer in the oxidized or reduced state with various counter ions):

poly(3,4-ethylenedioxythiophene) and its derivatives

polythiophene and its derivatives,

polypyrrole and its derivatives,

polyaniline and its derivatives,

polyacetylene and its derivatives,

poly(para-phenylenevinylene) and its derivatives,

polypyridine and its derivatives,

polyfluorene and its derivatives, and

polyindole and its derivatives,

and combinations thereof.

Organic additive materials may include, but are not limited to, the following (organic compounds of sulfoxide, multiple polar groups, such as hydroxyl group or nitro and hydroxyl group): sorbitol, erythritol, 1,4-dioxane-2,3-diol, threitol, arabinose, lyxose, ribose, xylose, xylulose, pentaerythritol, arabitol, xylitol, fucose, fructose, galactose, glucose, inositol, mannose, sorbose, iditol, mannitol, pinitol, 2-hydroxyethyl dodecyl sulfoxide, 4-bromophenyl methyl sulfoxide; Polyvinylalcohol, poly(ethyleneoxide), poly(ethylene glycol); and derivatives of these compounds, such as addition of an epoxy group, carbon-carbon double bond so that addition or crosslinking can take place

The following examples describe several simple and practical ways for the development of electric glue using conducting polymer. Results for polymer light-emitting diodes and polymer photovoltaic cells using this electrically conducting polymer glue in some examples are also described in the next section. These are to be taken as examples and not as limiting the general concepts of the invention.

### EXAMPLES

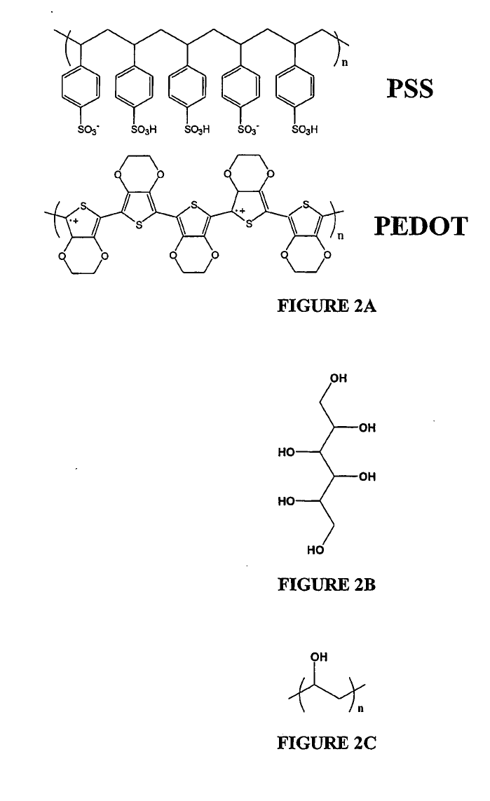

A poly(3,4-ethylenedioxythiophene)poly(styrenesulfonate) (PEDOT:PSS) solution (Baytron P) was purchased from Bayer Corporation. Three ways were carried out to modify the PEDOT:PSS film as electric glue (Chemical structure in Scheme 1; see FIG. 2). The first way was to add D-sorbital, or meso-erythritol into the PEDOT:PSS solution. The polymer film was formed by spin-coating this blended solution onto various substrates, such as glass/ITO, plastic/ITO, plastic, and glass. After they were baked at 90° C. for 60 minutes, the blended film was used for the lamination. In the next two ways, PEDOT:PSS films were formed on the substrates by spin-coating the aqueous PEDOT:PSS solution. In the second way a layer of D-sorbitol was thermally deposited on the PEDOT:PSS film, and in the third way the D-sorbitol layer was formed by spin-coating aqueous solution of D-sorbitol or D-sorbitol and poly(vinyl alcohol). PEDOT:PSS (D-sorbitol) will be used for the PEDOT:PSS film blended with D-sorbitol or coated with a D-sorbitol layer in the following examples. The substrate coated with PEDOT:PSS (D-sorbitol) was laminated with another substrate or organic film at a temperature of 130° C. for twenty minutes. The lamination effect was checked after the temperature was lowered to room temperature.

Polymer light-emitting diodes fabricated through a lamination process using this PEDOT:PSS electric glue was fabricated through this process (Scheme 2). At first, PEDOT:PSS film was formed on plastic/ITO substrate (used as anode in the device) by spin-coating PEDOT:PSS aqueous solution. After baking at 100° C., a layer of D-sorbitol with a thickness of 10 nm was formed on the PEDOT:PSS film through a thermal deposition or spin-coating process. (An alternative way is to form the PEDOT:PSS (D-sorbitol) layer by spin-coating aqueous solution of PEDOT:PSS and D-sorbitol). Aluminum (Al) (used as cathode in the device) was thermally deposited on another plastic substrate, and an MEH-PPV solution was subsequently spin-coated on this plastic/Al substrate. The two substrates were put together with the D-sorbitol layer facing the MEH-PPV layer. The lamination process was completed by heating at 120-140° C. in vacuum for twenty minutes. Polymer photovoltaic cells were fabricated through a similar process. The only difference is that the polymer semiconductor layer is a blend of MEH-PPV and methanofullerene (phenyl C61-butyric acid methyl ester) (PCBM) or P3HT and PCBM for the polymer photovoltaic cell. The devices were tested in a dry box filled with nitrogen.

A PEDOT:PSS film without any additive on any kind of substrate could not laminate two films at room or high temperature, that is, PEDOT:PSS could not be directly used as electric glue. When the PEDOT:PSS film was obtained from the PEDOT:PSS aqueous solution blended with D-sorbitol or the PEDOT:PSS film was coated with a thin layer of D-sorbitol, the PEDOT:PSS (D-sorbitol) film can laminate two substrates after a heating process. One substrate was a flexible substrate, such plastic, or plastic/ITO, and another substrate was a flexible or rigid substrate, such as plastic, plastic/ITO, glass, or glass/ITO. The PEDOT:PSS (D-sorbitol) was formed on either of the laminated substrates. The lamination could also take place between a plastic or glass substrate (coated or not coated with ITO) and a film of polymer semiconductor, such as poly(2-methoxy-5-(2′-ethyl-hexyloxy)-p-phenylene vinylene) (MEH-PPV) and poly(3-hexylthiophene) (P3HT). The PEDOT:PSS (D-sorbitol) film was formed on the former substrate.

The blended film of PEDOT:PSS and D-sorbitol has a thickness of 30-50 nm. When it has a two-layer structure, the PEDOT:PSS layer has a thickness of 30 nm and the D-sorbitol layer has a thickness of 10 nm. This PEDOT:PSS (D-sorbitol) can laminate the two substrates well electrically. When a glass (or plastic)/ITO substrate was laminated with a plastic (or glass)/ITO substrate, the resistance through the two laminated ITO/plastic substrates is almost the same as that through an ITO/plastic substrate. The blend of D-sorbitol into PEDOT:PSS or additional thin layer of D-sorbitol on PEDOT:PSS film does not lower the conductivity of the PEDOT:PSS film. Actually, the conductivity of such PEDOT:PSS film was enhanced by more than two orders in magnitude. As reported by our laboratory and other laboratories, a blend of polyalcohol into PEDOT:PSS greatly enhances the conductivity of PEDOT:PSS. (See Ouyang, J., Xu, Q., Chu, C. W., Yang, Y., Li, G. & Shinar, J. On the mechanism of conductivity enhancement in poly(3,4-ethylenedioxythiophene)-poly(styrene sulfonate) film through solvent treatment. Polymer 45, 8443-8450 (2004); Ouyang, J., Chu, C. W., Chen., F. C, Xu, Q. & Yang, Y. High-conductivity poly(3,4-ethylenedioxythiophene):poly(styrene sulfonate) film and its application in polymer optoelectronic devices. Adv. Fund. Mater. 15, 203-208 (2005); Pettersson L. A. A., Ghosh, S. & Inganäs, O. Optical anisotropy in thin films of poly(3,4-ethylenedioxythiophene)/poly(4-styrenesulfonate). Org. Electron. 3, 143-148 (2002); Kim, J. Y., Jung, J. H., Lee, D. E. & Joo, J. Enhancement of electrical conductivity of poly(3,4-ethylenedioxythiophene)/poly(4-styrenesulfonate) by a change of solvents. Synth. Met. 126, 311-316 (2002); and Kim, W. H., Mäkinen, A. J., Nikolov, V., Shashidhar, R., Kim, H. & Kafafi, Z. H. Molecular organic light-emitting diodes using highly conducting polymers as anodes Appl. Phys. Lett. 80, 3844-3846 (2002).) We also find that the conductivity enhancement was observed when the PEDOT:PSS is treated with a liquid polyalcohol or dimethylsulfoxide or dimethylformamide.

D-sorbitol has a melting point of 98-100° C. When the temperature is higher than this melting point, D-sorbitol becomes liquid and gluey. It can even laminate two stainless steel plates very well. The PEDOT:PSS(D-sorbitol) electric glue could laminate two films very well mechanically. When a plastic/ITO substrate coated with a PEDOT:PSS layer and a D-sorbitol layer was laminated with a glass/ITO substrate, the lamination was so good that the PEDOT:PSS layer transferred to the glass/ITO substrates when the two laminated substrates were separated by force. PEDOT:PSS (D-sorbitol) can laminate well with a polymer semiconductor. A test was performed through the following process: first, PEDOT:PSS (D-sorbitol) film was formed on a plastic/ITO substrate. The D-sorbitol layer had a thickness of 10 nm and was thermally deposited using a patterned shade mask. Then, this substrate was laminated with a glass substrate coated with a MEH-PPV of 100 nm at 130° C. After cooling to room temperature, the laminated two substrates were separated by force. The MEH-PPV was transferred to the plastic/ITO substrate, and the transferred MEH-PPV copied the pattern of the D-sorbitol layer well, that is, only the part of the MEH-PPV film that contacted with D-sorbitol was transferred while the part without contact with D-sorbitol was not transferred.

PEDOT:PSS film has high transparency in the visible range and has been widely used as the buffer layer or electrode in optoelectronic devices, such as polymer or organic light-emitting diodes and photovoltaic cells. Here we demonstrate that these optoelectronic devices could be fabricated through a lamination process using the electric glue of PEDOT:PSS. The schematic fabrication process for the polymer light-emitting diodes is shown in FIGS. 1A-1C. At first, the two parts (called anode and cathode part in this example) were fabricated separately. The substrate for the anode part is a plastic coated with 50 nm ITO. PEDOT:PSS film was spin-coated on this substrate, and D-sorbitol was thermally deposited. The substrate for the cathode part is a plastic. Al was thermally deposited on the plastic substrate by thermal evaporation, and MEH-PPV film was subsequently spin-coated. Then, these cathode and anode parts were laminated together with the D-sorbitol layer touching to the MEH-PPV layer. A mild pressure was applied to both sides to make the two parts contact. This laminated structure was put in a vacuum oven and evacuated to avoid the oxidation of the MEH-PPV film. It was treated at 130° C. in vacuum for about 30 minutes. After the temperature lowered to room temperature, the laminated device was transferred to a dry box filled with nitrogen for the electric test.

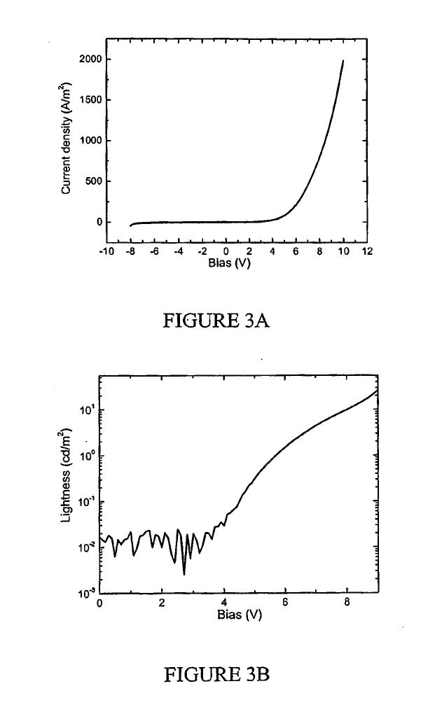

The laminated area of the device emits light homogeneously. The current-voltage and light-voltage curve of the device are presented in FIGS. 3A and 3B. The current-voltage curve indicates a good diode behavior. The turn-on voltage for the light is 3.6 V, and the efficiency is 0.017 cd/A. This performance is comparable to the device of Al/MEH-PPV/PEDOT:PSS/ITO/glass fabricated through the conventional bottom-to-top process. This indicates that the cathode and anode parts have a good contact.

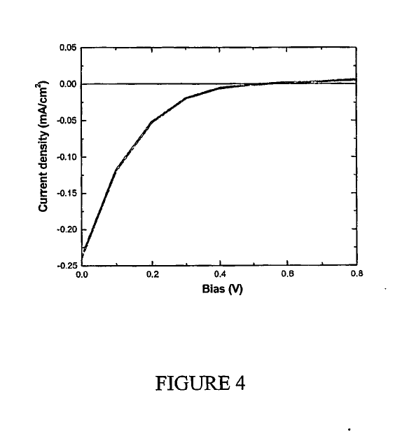

Polymer photovoltaic cells were fabricated through a similar process. The only difference is the materials of the active layer. FIG. 4 is the current-voltage curve of a laminated device with the P3HT and PCBM as the active materials. The open circuit voltage is 0.54 V. It is close to that of the device fabricated through a conventional process. The short-circuit current is 0.23 mA/cm².

In conclusion, several methods to modify PEDOT:PSS to be electric glue was described in the examples. This electric glue using conducting polymer laminated various substrates well, and the laminated substrates exhibit good electric and mechanical contact. Polymer light-emitting diodes fabricated through a lamination process using the conducting polymer electric glue exhibit comparable performance to the device fabricate through a conventional bottom-to-top process. Polymer photovoltaic cells fabricated by such a lamination process was described as well in the examples. This conducting polymer electric glue provides a new application for the conducting polymer and can solve the problem of soldering plastic chips. It also can provide a simple and practical way for roll-to-roll fabrication of organic electronic devices.

The embodiments illustrated and discussed in this specification are intended only to teach those skilled in the art the best way known to the inventors to make and use the invention. Nothing in this specification should be considered as limiting the scope of the present invention. The above-described embodiments of the invention may be modified or varied, and elements added or omitted, without departing from the invention, as appreciated by those skilled in the art in light of the above teachings. It is therefore to be understood that, within the scope of the claims and their equivalents, the invention may be practiced otherwise than as specifically described.

We claim:

1. An electronic or electro-optic device, comprising:
a first device component; and
a second device component attached to said first device component by a conducting polymer glue disposed between at least a portion of said first device component and said second device component,
wherein said conducting polymer glue provides an electrically conducting and mechanical connection between said first device component and said second device component.

2. An electronic or electro-optic device according to claim 1, wherein said first and second device components are first and second device layers, respectively, that are laminated together by said conducting polymer glue.

3. An electronic or electro-optic device according to claim 1, wherein said first and second device components are each a device component constructed from at least one of a metal, an insulator a semiconductor and an organic material.

4. An electronic or electro-optic device according to claim 1, wherein said conducting polymer glue comprises a conducting polymer selected from the group consisting of
poly(3,4-ethylenedioxythiophene) and its derivatives,
polythiophene and its derivatives,
polypyrrole and its derivatives,
polyaniline and its derivatives,
polyacetylene and its derivatives,
poly(para-phenylenevinylene) and its derivatives,
polypyridine and its derivatives,
polyfluorene and its derivatives, and
polyindole and their derivatives.

5. An electronic or electro-optic device according to claim 1, wherein said conducting polymer glue comprises an organic additive selected from the group consisting of sorbital, erythritol, 1,4-dioxane-2,3-diol, threitol, arabinose, lyxose, ribose, xylose, xylulose, pentaerythritol, arabitol, xylitol, fucose, fructose, galactose, glucose, inositol, mannose, sorbose, iditol, mannitol, pinitol, 2-hydroxyethyl dodecyl sulfoxide, 4-bromophenyl methyl sulfoxide, polyvinylalcohol, poly(ethyleneoxide), poly(ethylene glycol), and derivatives including an addition of an epoxy group and carbon-carbon double bonds so that addition or crosslinking can be provided.

6. An electronic or electro-optic device according to claim 4, wherein said conducting polymer glue comprises an organic additive selected from the group consisting of sorbital, erythritol, 1,4-dioxane-2,3-diol, threitol, arabinose, lyxose, ribose, xylose, xylulose, pentaerythritol, arabitol, xylitol, fucose, fructose, galactose, glucose, inositol, mannose, sorbose, iditol, mannitol, pinitol, 2-hydroxyethyl dodecyl sulfoxide, 4-bromophenyl methyl sulfoxide, polyvinylalcohol, poly(ethyleneoxide), poly(ethylene glycol), and derivatives including an addition of an epoxy group and carbon-carbon double bonds so that addition or cross linking can be provided.

7. A method of producing an electronic or electro-optic device, comprising:
providing a first device component;
providing a second device component proximate said first device component; and
attaching said first device component to said second device component with a conducting polymer glue,
wherein said conducting polymer glue provides an electrically conducting and mechanical connection between said first device component and said second device component.

8. A method of producing an electronic or electro-optic device according to claim 7, wherein said attaching said first device component to said second device component includes applying said conducting polymer glue to at least one of said first and second device components and bringing the other of said first and second device components into contact with said conducting polymer glue, and
wherein energy is applied to said conducting polymer glue.

9. A method of producing an electronic or electro-optic device according to claim 8, wherein said energy applied to said conducting polymer glue includes at least one of heating said conducting polymer glue, exposing said conducting polymer glue to light and passing an electrical current through said conducting polymer glue.

10. A method of producing an electronic or electro-optic device according to claim 8, wherein said applying said conducting polymer glue comprises spin coating a blend of a conducting polymer and an organic additive onto said at least one of said first and second device components.

11. A method of producing an electronic or electro-optic device according to claim 10, wherein said conducting polymer comprises a conducting polymer selected from the group consisting of
poly(3,4-ethylenedioxythiophene) and its derivatives,
polythiophene and its derivatives,
polypyrrole and its derivatives,
polyaniline and its derivatives,
polyacetylene and its derivatives,
poly(para-phenylenevinylene) and its derivatives,
polypyridine and its derivatives,
polyfluorene and its derivatives, and
polyindole and their derivatives.

12. A method of producing an electronic or electro-optic device according to claim 10, wherein said organic additive is selected from the group consisting of sorbital, erythritol, 1,4-dioxane-2,3-diol, threitol, arabinose, lyxose, ribose, xylose, xylulose, pentaerythritol, arabitol, xylitol, fucose, fructose, galactose, glucose, inositol, mannose, sorbose, iditol, mannitol, pinitol, 2-hydroxyethyl dodecyl sulfoxide, 4-bromophenyl methyl sulfoxide, polyvinylalcohol, poly(ethyleneoxide), poly(ethylene glycol), and derivatives including an addition of an epoxy group and carbon-carbon double bonds so that addition or crosslinking can be provided.

13. A method of producing an electronic or electro-optic device according to claim 11, wherein said organic additive is selected from the group consisting of sorbital, erythritol, 1,4-dioxane-2,3-diol, threitol, arabinose, lyxose, ribose, xylose, xylulose, pentaerythritol, arabitol, xylitol, fucose, fructose, galactose, glucose, inositol, mannose, sorbose, iditol, mannitol, pinitol, 2-hydroxyethyl dodecyl sulfoxide, 4-bromophenyl methyl sulfoxide, polyvinylalcohol, poly(ethyleneoxide), poly(ethylene glycol), and derivatives including an addition of an epoxy group and carbon-carbon double bonds so that addition or crosslinking can be provided.

14. A method of producing an electronic or electro-optic device according to claim 8, wherein said applying said conducting polymer glue comprises spin-coating a layer of a conducting polymer onto at least one of said first and second device components and spin-coating a layer of an organic additive onto said layer of said conducting polymer.

15. A method of producing an electronic or electro-optic device according to claim 14, wherein said conducting polymer comprises a conducting polymer selected from the group consisting of
poly(3,4-ethylenedioxythiophene) and its derivatives,
polythiophene and its derivatives,
polypyrrole and its derivatives,
polyaniline and its derivatives,
polyacetylene and its derivatives,
poly(para-phenylenevinylene) and its derivatives,
polypyridine and its derivatives,
polyfluorene and its derivatives, and
polyindole and their derivatives.

16. A method of producing an electronic or electro-optic device according to claim 14, wherein said organic additive is selected from the group consisting of sorbital, erythritol, 1,4-dioxane-2,3-diol, threitol, arabinose, lyxose, ribose, xylose, xylulose, pentaerythritol, arabitol, xylitol, fucose, fructose, galactose, glucose, inositol, mannose, sorbose, iditol, mannitol, pinitol, 2-hydroxyethyl dodecyl sulfoxide, 4-bromophenyl methyl sulfoxide, polyvinylalcohol, poly(ethyleneoxide), poly(ethylene glycol), and derivatives including an addition of an epoxy group and carbon-carbon double bonds so that addition or crosslinking can be provided.

17. A method of producing an electronic or electro-optic device according to claim 15, wherein said organic additive is selected from the group consisting of sorbital, erythritol, 1,4-dioxane-2,3-diol, threitol, arabinose, lyxose, ribose, xylose, xylulose, pentaerythritol, arabitol, xylitol, fucose, fructose, galactose, glucose, inositol, mannose, sorbose, iditol, mannitol, pinitol, 2-hydroxyethyl dodecyl sulfoxide, 4-bromophenyl methyl sulfoxide, polyvinylalcohol, poly(ethyleneoxide), poly(ethylene glycol), and derivatives including an addition of an epoxy group and carbon-carbon double bonds so that addition or crosslinking can be provided.

18. A method of producing an electronic or electro-optic device according to claim 8, wherein said applying said conducting polymer glue comprises spin-coating a layer of a conducting polymer onto at least one of said first and second device components and thermally depositing an organic additive onto said layer of said conducting polymer.

19. A method of producing an electronic or electro-optic device according to claim 18, wherein said conducting polymer comprises a conducting polymer selected from the group consisting of
poly(3,4-ethylenedioxythiophene) and its derivatives,
polythiophene and its derivatives,
polypyrrole and its derivatives,
polyaniline and its derivatives,
polyacetylene and its derivatives,
poly(para-phenylenevinylene) and its derivatives,
polypyridine and its derivatives,
polyfluorene and its derivatives, and
polyindole and their derivatives.

20. A method of producing an electronic or electro-optic device according to claim 18, wherein said organic additive is selected from the group consisting of sorbital, erythritol, 1,4-dioxane-2,3-diol, threitol, arabinose, lyxose, ribose, xylose, xylulose, pentaerythritol, arabitol, xylitol, fucose, fructose, galactose, glucose, inositol, mannose, sorbose, iditol, mannitol, pinitol, 2-hydroxyethyl dodecyl sulfoxide, 4-bromophenyl methyl sulfoxide, polyvinylalcohol, poly(ethyleneoxide), poly(ethylene glycol), and derivatives including an addition of an epoxy group and carbon-carbon double bonds so that addition or crosslinking can be provided.

21. A method of producing an electronic or electro-optic device according to claim 19, wherein said organic additive is selected from the group consisting of sorbital, erythritol, 1,4-dioxane-2,3-diol, threitol, arabinose, lyxose, ribose, xylose, xylulose, pentaerythritol, arabitol, xylitol, fucose, fructose, galactose, glucose, inositol, mannose, sorbose, iditol, mannitol, pinitol, 2-hydroxyethyl dodecyl sulfoxide, 4-bromophenyl methyl sulfoxide, polyvinylalcohol, poly(ethyleneoxide), poly(ethylene glycol), and derivatives including an addition of an epoxy group and carbon-carbon double bonds so that addition or crosslinking can be provided.

22. A conducting polymer glue for connecting components of electronic or electro-optic devices, comprising:
a conducting polymer selected from the group consisting of
poly(3,4-ethylenedioxythiophene) and its derivatives,
polythiophene and its derivatives,
polypyrrole and its derivatives,
polyaniline and its derivatives,
polyacetylene and its derivatives,
poly(para-phenylenevinylene) and its derivatives,
polypyridine and its derivatives,
polyfluorene and its derivatives,
polyindole and their derivatives, and
an organic additive selected from the group consisting of sorbital, erythritol, 1,4-dioxane-2,3-diol, threitol, arabinose, lyxose, ribose, xylose, xylulose, pentaerythritol, arabitol, xylitol, fucose, fructose, galactose, glucose, inositol, mannose, sorbose, iditol, mannitol, pinitol, 2-hydroxyethyl dodecyl sulfoxide, 4-bromophenyl methyl sulfoxide, polyvinylalcohol, poly(ethyleneoxide), poly(ethylene glycol), and derivatives including an addition of an epoxy group and carbon-carbon double bonds so that addition or crosslinking can be provided,
wherein said conducting polymer glue is able to provide mechanical and electrical connection.

23. A conducting polymer glue for connecting components of electronic or electro-optic devices according to claim 22, wherein said conducting polymer is PEDOT:PSS and said organic additive is D-sorbitol, and wherein said conducting polymer glue is substantially transparent to light in a visible spectral range.
